(19) United States
(12) Patent Application Publication
(10) Pub. No.: US 2024/0321860 A1
(43) Pub. Date: Sep. 26, 2024

(54) ROW CELL CIRCUITS WITH ABRUPT DIFFUSION REGION WIDTH TRANSITIONS

(71) Applicant: QUALCOMM Incorporated, San Diego, CA (US)

(72) Inventors: Haining Yang, San Diego, CA (US); Junjing Bao, San Diego, CA (US); Hyunwoo Park, San Diego, CA (US); Kwanyong Lim, San Diego, CA (US)

(21) Appl. No.: 18/189,045

(22) Filed: Mar. 23, 2023

(51) Int. Cl. H01L 27/02; H01L 29/06; H01L 29/423; H01L 29/66; H01L 29/775; H01L 29/786; H03K 19/0948

(52) U.S. Cl. CPC H01L 27/0207; H01L 29/0673; H01L 29/42392; H01L 29/66439; H01L 29/66545; H01L 29/775; H01L 29/78696; H03K 19/0948

(57) ABSTRACT

Logic circuits are implemented in row cell circuits that include diffusion regions. Each diffusion region portion is employed by a transistor in a cell circuit. A current capacity of each transistor depends on a width of the diffusion region portion. A first diffusion region portion and a second diffusion region portion having different widths intersect along an axis, where the diffusion region of a row cell circuit abruptly transitions (e.g., at a square corner) in width. A gate disposed over the diffusion region along the intersection includes a first side on the first diffusion region portion and a second side on the second diffusion region portion. The transition occurring between the first side and the second side of the gate may be achieved by square corner features formed in the diffusion region. Such features were not previously achievable at small technology nodes due to mask pattern limitations.

### BACKGROUND

### I. Field of the Disclosure

The technology of the disclosure relates generally to logic circuits in an integrated circuit and, more particularly, to standard cells employed in a logic circuit.

### II. Background

Integrated circuits (ICs) may include various functions requiring a combination of memory circuits, analog circuits, and digital logic circuits on the same semiconductor die. Since the logic circuits can occupy a majority of the area of the semiconductor die, and there is a trend to reduce the sizes of semiconductor dies, there is a trend to reduce the sizes of logic circuits. Logic circuits are implemented in cell circuits (e.g., standard cell circuits in standard cells) arranged in rows of cell circuits referred to as row cell circuits. Each cell circuit includes at least one transistor, including a portion of a diffusion region on the semiconductor die, and the cell circuits in the same row include portions of the same diffusion region. Current carrying requirements for the transistors in cell circuits vary according to the types of logic circuits being implemented. Thus, cell circuits in a same row cell circuit may have different current requirements. The current carrying capacities of cell circuits in a row cell circuit can be individually adjusted by adjusting a width of the portion of the diffusion region employed by each cell circuit. A wider diffusion region has a greater current carrying capacity or greater drive strength. However, a transition in the width of the diffusion region between a wider portion and a narrower portion in a row cell circuit can waste area and cause circuit defects.

### SUMMARY

Aspects disclosed in the detailed description include row cell circuits with abrupt diffusion region width transitions. Related methods of fabricating row cell circuits with abrupt diffusion region width transitions are also disclosed. Logic circuits are implemented by cell circuits disposed in row cell circuits on a semiconductor substrate. Each diffusion region includes diffusion region portions disposed along a first axis in a first direction. Each diffusion region portion is employed by at least one transistor of a cell circuit. The current capacity of the transistor depends on a width of the diffusion region portion in a second direction orthogonal to the first direction. In an exemplary row cell circuit, a first diffusion region portion having a first width and a second diffusion region portion having a second width greater than the first width, intersect along a second axis extending in the second direction. In this regard, where the first diffusion region portion and the second diffusion region portion, the diffusion region in a row cell circuit abruptly transitions in width. An abrupt transition may be defined as a transition having a square corner or where a change in width in the second direction occurs over substantially no change in the first direction. A gate disposed over the diffusion region along the second axis at the intersection of the first diffusion region and the second diffusion region includes a first side on the first diffusion region portion and a second side on the second diffusion region portion. Thus, in some examples, the transition occurs between the first side and the second side of the gate where square (e.g., right-angle) corner features are formed in the diffusion region. In existing fabrication processes, the corners of the gates are rounded, causing the sides of the diffusion region to be tapered and transition gradually from one width to another due to limitations at smaller technology nodes. Such gradual transitions reduce area efficiency of the row cell circuit and create angles between a gate and a source/drain region that can increase electrical shorts and current leakage.

In a first exemplary aspect, a row cell circuit is disclosed. The row cell circuit comprises a diffusion region on a substrate, the diffusion region comprising a first diffusion region portion and a second diffusion region portion, each disposed along a first axis in a first direction. The first diffusion region portion and the second diffusion region portion intersect along a second axis in a second direction orthogonal to the first direction. The first diffusion region portion has a first width in the second direction, and the second diffusion region portion has a second width greater than the first width in the second direction. The row cell circuit further comprises a first gate disposed along the second axis on the diffusion region, wherein the first gate comprises a first gate first side on the first diffusion region portion and a first gate second side on the second diffusion region portion.

In another exemplary aspect, a method of fabricating a row cell circuit is disclosed. The method includes a diffusion region on a substrate, the diffusion region comprising a first diffusion region portion, and a second diffusion region portion, each disposed along a first axis in a first direction. Forming the diffusion region further comprises forming the first diffusion region portion and the second diffusion region portion intersecting along a second axis in a second direction orthogonal to the first direction, forming the first diffusion region portion having a first width in the second direction and forming the second diffusion region portion having a second width greater than the first width in the second direction. The method of fabricating the row cell circuit further includes forming a first gate along the second axis on the diffusion region, wherein the first gate comprises a first gate first side on the first diffusion region portion and a first gate second side on the second diffusion region portion.

In another exemplary aspect, an integrated circuit (IC) is disclosed. The IC includes a logic circuit disposed on a substrate, the logic circuit comprising a plurality of row cell circuits, each row cell circuit comprising a diffusion region on a substrate, the diffusion region comprising a first diffusion region portion and a second diffusion region portion, each disposed along a first axis in a first direction, wherein the first diffusion region portion and the second diffusion region portion intersect along a second axis in a second direction orthogonal to the first direction. The first diffusion region portion has a first width in the second direction, and the second diffusion region portion has a second width greater than the first width in the second direction. The logic circuit also includes a first gate disposed along the second axis on the diffusion region, wherein the first gate comprises a first gate first side on the first diffusion region portion and a first gate second side on the second diffusion region portion.

### BRIEF DESCRIPTION OF THE DRAWINGS

FIG. 1A is a top plan view of a conventional row cell circuit in which the diffusion region width tapers gradually between a portion having a narrower width and a portion having a wider width;

FIG. 1B and FIG. 1C are cross-sectional side views of the row cell circuit at cross-sections A-A′ and B-B′ in FIG. 1A to show diffusion regions of different widths;

FIG. 2 is a top plan view corresponding to FIG. 1A, at which diffusion regions are replaced by epitaxial source/drain regions, illustrating a defect caused by residual gate material at the apex of an intersection of the diffusion region and the gate;

FIG. 3 is a top plan view of an exemplary first row cell circuit in which the diffusion region abruptly changes in width from a first portion to a second portion where square corners are formed between the sides of a gate;

FIG. 4 is a flowchart illustrating an exemplary process for fabricating the row cell circuit in which the diffusion region abruptly changes in width from a first portion to a second portion where square corners are formed between the sides of a gate, including but not limited to the row cell circuit of FIG. 3;

FIGS. 5A1-5F2 include top views and cross-sectional views of exemplary stages of fabrication of a row cell circuit in which the diffusion region abruptly changes in width from a first portion to a second portion where square corners are formed between the sides of a gate, including but not limited to the row cell circuit, including but not limited to the row cell circuit in FIG. 3;

FIGS. 6A-6F are a flow chart of a process of fabricating the row cell circuit in the fabrication stages illustrated in FIGS. 5A1-5F2;

FIG. 7 is a block diagram of an exemplary wireless communications device, including integrated circuits (ICs) that can include row cell circuits in which the diffusion region abruptly changes in width from a first portion to a second portion where square corners are formed between the sides of a gate, including but not limited to the row cell circuit as shown in FIG. 3; and

FIG. 8 is a block diagram of an exemplary processor-based system that can include a row cell circuit in which the diffusion region abruptly changes in width from a first portion to a second portion where square corners are formed between the sides of a gate, including but not limited to the row cell circuit as shown in FIG. 3.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include row cell circuits with abrupt diffusion region width transitions. Related methods of fabricating row cell circuits with abrupt diffusion region width transitions are also disclosed. Logic circuits are implemented by cell circuits disposed in row cell circuits on a semiconductor substrate. Each diffusion region includes diffusion region portions disposed along a first axis in a first direction. Each diffusion region portion is employed by at least one transistor of a cell circuit. The current capacity of the transistor depends on a width of the diffusion region portion in a second direction orthogonal to the first direction. In an exemplary row cell circuit, a first diffusion region portion having a first width and a second diffusion region portion having a second width greater than the first width, intersect along a second axis extending in the second direction. Between the first diffusion region portion and the second diffusion region portion, the diffusion region in a row cell circuit abruptly transitions in width. An abrupt transition may be defined as a transition at a square corner or where a change in width in the second direction occurs over substantially no change in the first direction. A gate disposed over the diffusion region along the second axis at the intersection of the first diffusion region and the second diffusion region includes a first side on the first diffusion region portion and a second side on the second diffusion region portion. Thus, the transition occurs between the first side and the second side of the gate, where square (e.g., right-angle) corner features are formed in the diffusion region. In existing fabrication processes, the corners are rounded, causing the sides of the diffusion region to be tapered and transition gradually from one width to another due to limitations at smaller technology nodes. Such gradual transitions reduce area efficiency of the row cell circuit and create angles between a gate and a source/drain region that can increase electrical shorts and current leakage.

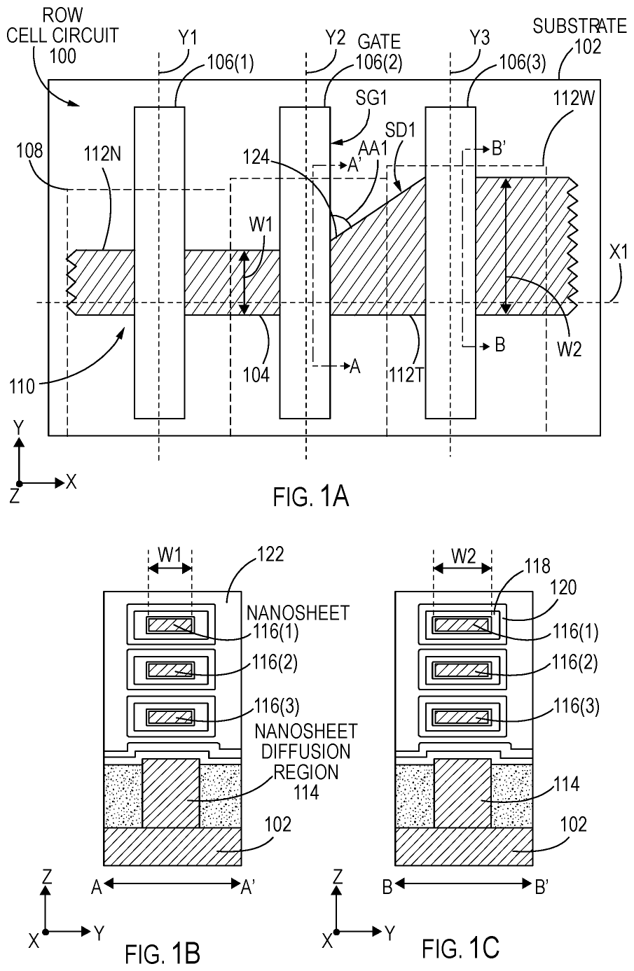

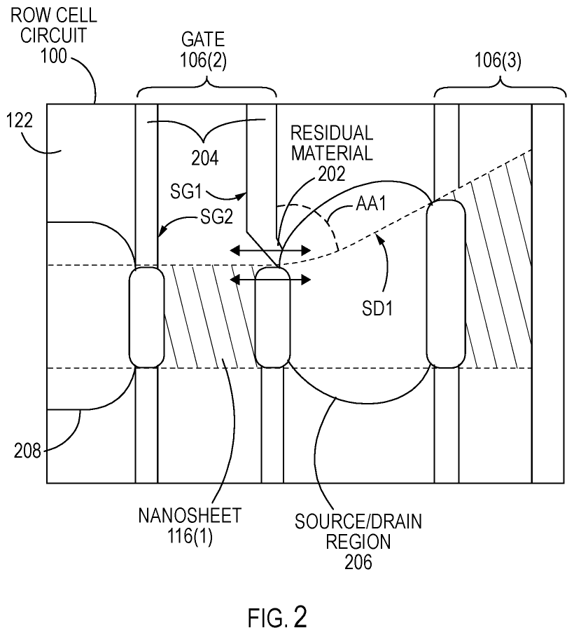

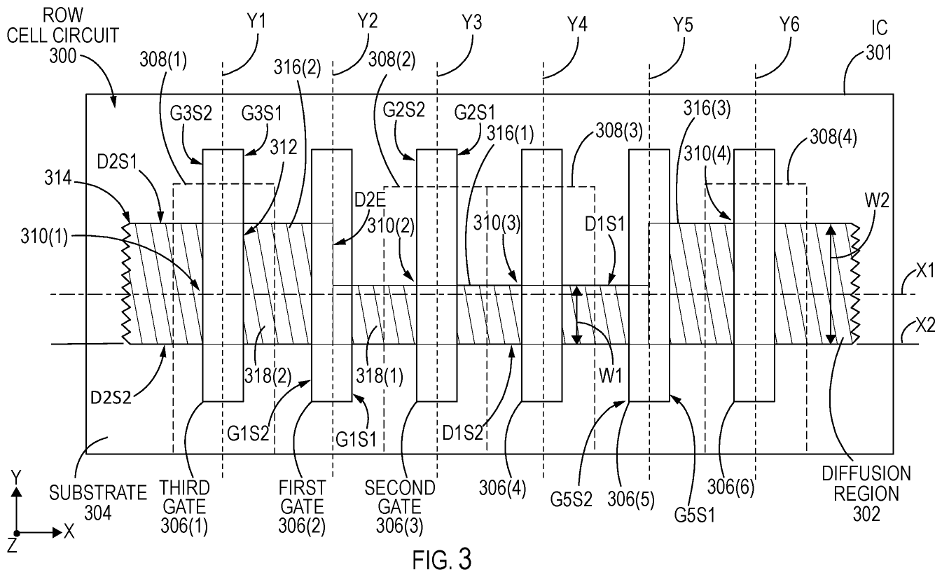

Before describing the exemplary row cell circuit 300 with reference to FIG. 3, a conventional row cell circuit 100, and the problems encountered therewith are explained with reference to FIGS. 1A-1C and FIG. 2.

FIG. 1A is a top plan view of a row cell circuit 100 that is disposed on a substrate 102 (e.g., a semiconductor substrate) and includes a diffusion region 104 and gates 106(1)-106(3). A plurality of cell circuits 108 are formed in the row cell circuit 100, and each cell circuit 108 includes at least one transistor 110 that employs a portion of the diffusion region 104. The diffusion region 104 extends along a longitudinal axis X1 in a first direction or row direction (e.g., the X-axis direction) of the row cell circuit 100. The row cell circuit 100 may extend further in the row direction than shown in FIG. 1A and may include additional gates disposed over the diffusion region 104. The gates 106(1)-106(3) are disposed along longitudinal axes Y1-Y3 extending in a width direction or second direction (e.g., the Y-axis direction), which is orthogonal to the row direction. The gates 106(1)-106(3) may be used to control current flow in the transistors 110.

The diffusion region 104 includes a first portion 112N having a first width W1 in the width direction and a second portion 112W having a second width W2 in the width direction. The diffusion region 104 also includes a third portion 112T (a transition portion), that changes in width between the gate 106(2) and the gate 106(3). Portions of the diffusion region 104 having different widths provide the transistors 110 with different current carrying capabilities according to requirements of the cell circuits 108 formed in the row cell circuit 100. Any of the gates 106(1)-106(3) in FIG. 1A may be configured as active gates for controlling transistors 110 in cell circuits 108 of the row cell circuit 100.

FIGS. 1B and 1C are cross-sectional side views at cross-sections A-A′ and B-B′ in the gates 106(2) and 106(3) and show that the transistors 110 are gate-all-around (GAA) transistors. The gates 106(2) and 106(3) are both shown as gates for active transistors, but either one may instead be a dummy gate. The diffusion region 104 is formed from the substrate 102, which is a semiconductor material such as silicon (Si). The diffusion region 104 may be either a first type, doped with a trivalent dopant to form a P-type material or a second type, doped with a pentavalent dopant to form an N-type material. The row cell circuit 100 may include another diffusion region (not shown) of the other type, in addition to and opposite to the diffusion region 104, such that cell circuits 108 in the row cell circuit 100 may include both an N-type and a P-type transistor 110 to form a complementary metal-oxide semiconductor (CMOS) circuit.

The diffusion region 104 includes a nanosheet diffusion region 114 extending vertically (in the Z-axis direction) from the substrate 102 and nanosheets 116(1)-116(3). The diffusion region 104, as shown in the top view of the row cell circuit 100 in FIG. 1A, corresponds to a top view of the nanosheet 116(1) before the nanosheets 116(1)-116(3) are removed from between the gates 106(1)-106(3). The diffusion region 104, as shown in FIG. 1A, also corresponds to a view of the nanosheet diffusion region 114 after removal of the nanosheets 116(1)-116(3) because the nanosheet diffusion region 114 has a same shape (in the X-axis direction and the Y-axis direction) as the nanosheet 116(1). After the nanosheets 116(1)-116(3) have been removed from between the gates 106(1)-106(3), the nanosheets 116(1)-116(3) within the gates 106(1)-106(3) provide channel regions for the transistors 110. Source/drain regions will be coupled to exposed ends of the nanosheets 116(1)-116(3) within the active ones of the gates 106(1)-106(3) to form transistors 110 for cell circuits 108.

In FIG. 1B, at the cross-section A-A, the nanosheets 116(1)-116(3) have the first width W1, and in FIG. 1C, at cross-section B-B, the nanosheets 116(1)-116(3) have the second width W2. Current carrying capacity of the nanosheets 116(1)-116(3) at the cross-sections A-A and B-B are directly related to the widths W1 and W2, respectively. Therefore, the current carrying capacity in the nanosheets 116(1)-116(3) in cross-section B-B in FIG. 1C is greater than the current carrying capacity of the nanosheets 116(1)-116(3) at cross-section A-A in FIG. 1B. For this reason, in some examples, the gates 106(1) and 106(3) may be employed to control transistors 110 having different capacities, and gate 106(2) may be a dummy gate rather than an active gate, as shown in FIG. 1A.

FIGS. 1B and 1C also show features within the gates 106(2) and 106(3) that are not shown in FIG. 1A, including a work function layer 118 and a dielectric layer 120 that isolate a gate material 122 from the nanosheets 116(1)-116(3). The gate material 122 is formed around all sides of the perimeters of each nanosheet 116(1)-116(3). Because the gate material 122 extends around all sides of the gates 106(2) and 106(3), a voltage applied to the gates 106(2) and 106(3) can control current flow through the nanosheets 116(1)-116(3).

A problem is encountered with the conventional row cell circuit 100 where the diffusion region 104 transitions (i.e., gradually tapers in width as measured in the second direction) between the first width W1 and the second width W2 over the distance between gate 106(2) and gate 106(3) in this example. In fabrication, a mask pattern used in a photolithographic process sets the widths (e.g., W1 and W2) of adjacent portions of the diffusion region 104 corresponding to transistor current requirements. However, as technology nodes become smaller, the diffusion region 104 does not abruptly change in shape from the width W1 to the width W2. Consequently, the diffusion region 104 tapers in width gradually in the row direction between the gates 106(2) and 106(3).

The gradual taper creates an angle AA1 at an intersection of a first side SD1 of the diffusion region 104 and a first side SG1 of the gate 106(2). A gradual taper occupies a portion of the row cell circuit 100 (i.e., extending in the row direction) for the width transition, which reduces area efficiency of the row cell circuit 100. The angle AA1 is an acute angle (i.e., less than a 90-degree angle), which can make it difficult to etch out the gate material 122 from an apex 124 of the intersection of the diffusion region 104 and the gate 106(2) during the process of forming the gates 106(1)-106(3) on the diffusion region 104. Residual gate material 122 can lead to electrical shorts.

FIG. 2 is a close-up top plan view of the row cell circuit 100 showing in detail the consequences of residual material 202 of the gate material 122 that is not removed from the apex 124 (see FIG. 1A) between the gate 106(2) and the nanosheets 116(1)-116(3). In FIG. 2, the row cell circuit 100 is shown at a later stage of fabrication than in FIG. 1A. Here, insulation layers 204 have been formed on opposite sides of the gate material 122 of the gate 106(2). Due to the acute angle AA1, residual material 202 of the gate material 122 has not been removed. In detail, the process of patterning the gate material 122 to form the gates 106(1)-106(3) includes a step of etching away the gate material 122 in places not covered by a mask pattern (not shown). However, on a side SG1 of the gate material 122 of the gate 106(2), a side SD1 of the nanosheet 116(1) intersects with the gate material 122 at an acute angle AA1 at the apex 124 (see FIG. 1A). Here, the granularity or resolution of the etching process relative to the dimensions of the technology make it difficult for the etching process to remove all gate material 122. For this reason, the residual material 202 may not be removed. When insulating layer 204 is formed on sides SG1 and SG2 of the gate 106(2), a thickness of the insulation layer 204 over the residual material 202 may be thinner than expected where the residual material 202 extends outside the mask pattern of the gate 106(2).

After the nanosheet 116(1) is removed from between the gates 106(1)-106(3), a source/drain region 206 (e.g., epitaxial material) is formed between the gates 106(2) and 106(3), coupled to exposed ends of the nanosheets 116(1)-116(3). Another source/drain region 208 is also formed between the first gate 306(2) and the third gate 306(1). Where the insulation layer 204 has a reduced thickness over the residual material 202, there may be a direct short or a short path through the insulation layer 204 through which current may leak between the gate material 122 and the source/drain region 206 when there is a voltage potential between them.

FIG. 3 is a top plan view of an exemplary row cell circuit 300 on an integrated circuit (IC) 301, the row cell circuit 300 including a diffusion region 302 on a substrate 304 and gates 306(1)-306(6) disposed on the diffusion region 302. The row cell circuit 300 includes cell circuits 308(1)-308(4) that include transistors 310(1)-310(4), each of which is disposed on a corresponding portion of the diffusion region 302. The IC 301 may include a plurality of row cell circuits corresponding to the row cell circuit 300 to form logic circuits.

The top view in FIG. 3 illustrates the width of the diffusion region 302, which may include a nanosheet 312 (which may be a top nanosheet of a stack of nanosheets) disposed above a nanosheet diffusion region 314 on and extending from the substrate 304. The nanosheet 312 and the nanosheet diffusion region 314 correspond to the nanosheet 116(1) and the nanosheet diffusion region 114 in FIGS. 1B and 1C. The diffusion region 302 includes a first diffusion region portion 316(1), a second diffusion region portion 316(2), and a third diffusion region portion 316(3), each disposed along a longitudinal axis X1 in a first direction or row direction (e.g., X-axis direction) in FIG. 3. The first diffusion region portion 316(1) and the second diffusion region portion 316(2) intersect along a second axis Y2 in a second direction (e.g., the Y-axis direction) orthogonal to the first direction. The first diffusion region portion 316(1) and the third diffusion region portion 316(3) intersect along a third axis in the second direction. The first diffusion region portion 316(1) has a first width W1 in the second direction, and the second diffusion region portion 316(2) and the third diffusion region portion 316(3) each have a second width W2 greater than the first width W1 in the second direction. The gates 306(1)-306(6) extend along axes Y1-Y6, respectively, in the second direction. A first gate 306(2) is disposed along the second axis Y2, such that a first gate first side G1S1 of the first gate 306(2) is on the first diffusion region portion 316(1) and a first gate second side G1S2 of the first gate 306(2) is on the second diffusion region portion 316(2).

In an exemplary aspect, the diffusion region 302 abruptly transitions between the first width W1 and the second width W2 between the first gate first side G1S1 and the first gate second side G1S2 of the second gate 306(2), where the first diffusion region portion 316(1) and the second diffusion region portion 316(2) intersect. A similar abrupt transition in width of the diffusion region 302 occurs between a first side G5S1 and a second side G5S2 of the gate 306(5). An abrupt transition is defined as a transition at a square corner or where a change in width in the second direction occurs over substantially no change in the first direction.

Where the first diffusion region portion 316(1) intersects with the second diffusion region portion 316(2) and the third diffusion region portion 316(3), square corners (e.g., having right angles) are formed in the diffusion region 302 (as explained below) despite limitations of the fabrication methods and the technology node size. The square corner avoids gradual changes in the width of the diffusion region 302 and avoids acute angles between the sides of the gates 306(1)-306(6) and the diffusion region 302. Instead, a first portion first side D1S1 of the first diffusion region portion 316(1) and a first portion second side D1S2 of the first diffusion region portion 316(1) intersect at square corners (e.g., with angles of approximately 90 degrees) with the first gate first side G1S1 of the first gate 306(2) and with a second gate first side G2S2 of the second gate 306(3). A second portion first side D2S1 of the second diffusion region portion 316(2) and a second portion second side D2S2 of the second diffusion region portion 316(2) intersect at square corners (e.g., right angles) with the first gate second side G1S2 of the first gate 306(2) and with the third gate first side G3S1 of the third gate 306(1). At such square corners, residual gate material is more readily removed during fabrication and, therefore, electrical shorts and current leakage are reduced compared to the row cell circuit 100 illustrated in FIGS. 1A and 2. In addition, because the diffusion region 302 width transition is abrupt and does not gradually taper over a distance in the first direction, the row cell circuit 300 is more area efficient than the row cell circuit 100 in FIG. 1.

In this regard, the first gate first side G1S1 is disposed on the first diffusion region portion 316(1), and the first gate second side G1S2 of the first gate 306(2) is disposed on the second diffusion region portion 316(2). The diffusion region 302 includes the first diffusion region portion 316(1), having the first width W1 in the width direction, and the second diffusion region portion 316(2) having the second width W2 greater than the first width W1 in the second direction. The first diffusion region portion 316(1) includes the first portion first side D1S1 and the first portion second side D1S2, each orthogonal to the first gate first side G1S1 of the first gate 306(2). The second diffusion region portion 316(2) includes a second portion first side D2S1 and a second portion second side D2S2 that are each orthogonal to the first gate second side G1S2 of the first gate 306(2). As shown in FIG. 3, the first portion second side D1S2 and the second portion side D2S2 extend along an axis X2 in the first direction.

The second diffusion region portion 316(2) includes a second portion end D2E disposed along the axis Y2, such that the second portion end D2E is orthogonal to the first portion first side D1S1 of the first diffusion region portion 316(1). In other words, the first portion first side D1S1 is at or approximately at a right angle to the second portion end D2E. The second portion first side D2S1 is also orthogonal to the second portion end D2E. Due to the transition between the first width W1 of the first diffusion region portion 316(1) and the second width W2 of the second diffusion region portion 316(2) in this example, the first gate 306(2) is a dummy gate rather than an active gate for controlling a transistor.

In some examples, the nanosheet 312 is within the first gate 306(2) (dummy gate) above the nanosheet diffusion region 314 in the vertical (Z-axis) direction. The nanosheet 312 is the same material (doped semiconductor material) as the nanosheet diffusion region 314. In this example, the nanosheet 312 includes a first nanosheet portion 318(1) having the first width W1 in the second direction, a second nanosheet portion 318(2) having the second width W2, and a square corner between (at the intersection of) the first nanosheet portion 318(1) and the second nanosheet portion 318(2).

The second gate 306(3) is an active gate in the row cell circuit 300 disposed along the axis Y3, as shown in FIG. 3, adjacent to the first gate first side G1S1 of the second gate 306(2). The nanosheet 312 is within the second gate 306(3), between the second gate first side G2S1 and the second gate second side G2S2, and above the nanosheet diffusion region 314 in the vertical (Z-axis) direction. Similarly, the third gate 306(1) in the row cell circuit 300 is disposed along the axis Y1 and has a third gate first side G3S1 and a third gate second side G3S2. The third gate 306(1) is adjacent to the first gate second side G1S2 of the first gate 306(2). The nanosheet 312 is within the third gate 306(1), between the third gate first side G3S1 and the third gate second side G3S2, and above the nanosheet diffusion region 314 in the vertical (Z-axis) direction.

The row cell circuit 300 includes the cell circuits 308(1)-308(4) that include, respectively, the transistors 310(1)-310(4) controlled by the third gate 306(1), the second gate 306(3), and the gates 306(4), and 306(6), respectively. The transistors 310(1) and 310(4) in the second and third diffusion region portions 316(2) and 316(3), having the second width W2 have a greater current capacity than the transistors 310(2) and 310(3) in the first diffusion region portion 316(1) having the first width W1. In this example, the first gate 306(2) and the gate 306(5) are dummy gates that are not active.

The first diffusion region portion 316(1) extends between the first gate first side G1S1 and the second gate second side G2S2, with the first portion first side D1S1 and the first portion second side D1S2 each being orthogonal to the first gate first side G1S1 and the second gate second side G2S2. The nanosheet 312 is removed from between the gates 306(1)-306(6), where source/drain regions 206 and 208 (as shown in FIG. 2) are grown for the transistors 310(1)-310(4). The source/drain region 206 between the first gate 306(2) and the second gate 306(3) are electrically coupled to the nanosheet 312 in the second gate 306(3). The second diffusion region portion 316(2) extends between the first gate second side G1S2 and the third gate first side G3S1, with the second portion first side D2S1 and the second portion second side D2S2 each being orthogonal to the first gate second side G1S2 and the third gate first side G3S1. The source/drain region 208 between the first gate 306(2) and the third gate 306(1) are electrically coupled to the nanosheet 312 in the third gate 306(1). The first portion first side D1S1, first portion second side D1S2, second portion first side D2S1, and second portion second side D2S2 of the diffusion region 302 are surfaces extending vertically (in the Z-axis direction) from the substrate 304 in a direction orthogonal to the first direction and the second direction.

The first gate 306(2) electrically isolates the source/drain regions 206 and 208 from each other, and the gate 306(5) electrically isolates source/drain regions on opposite sides of the fifth gate 306(5) from each other. The electrical isolation may be implemented in different manners, depending on fabrication methods of the dummy gates. However, despite the forms of such dummy gates, the nanosheet diffusion region 314, including the square corners at second gate 306(2) and the gate 306(5), is maintained, and the nanosheet 312 may also be maintained within the second gate 306(2) and the gate 306(5). It should be understood that, in some examples in which the diffusion region 302 includes a stack of three nanosheets represented by the nanosheet 312, the cross-sectional views in FIGS. 1B and 1C would also represent cross-sections taken along the axis Y3 in the second gate 306(3), in which the nanosheet 312 has the first width W1, and along the axis Y6 in the gate 306(6), in which the nanosheet 312 has the second width W2.

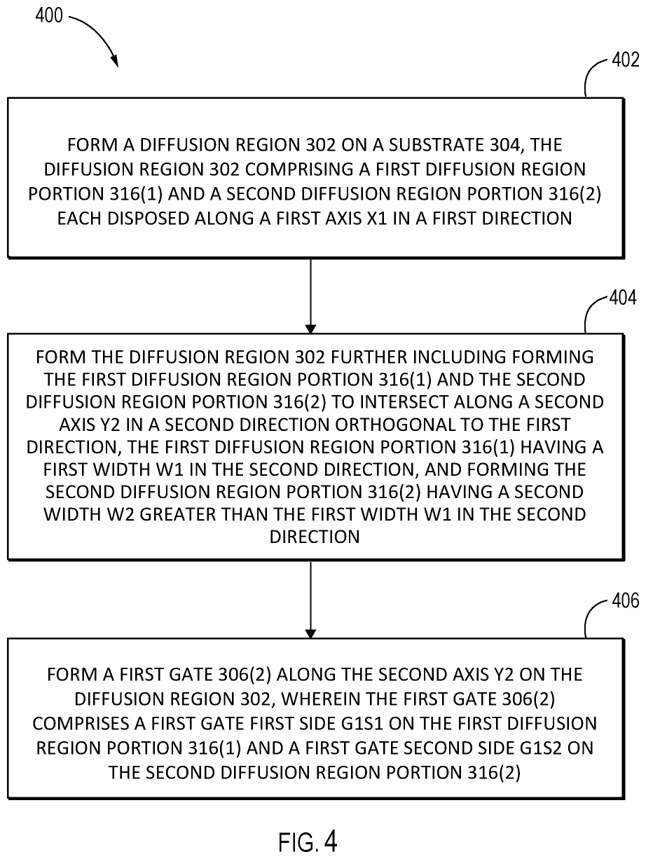

FIG. 4 is a flow chart illustrating an exemplary method 400 of fabricating the row cell circuit 300. The method 400 includes forming a diffusion region 302 on a substrate 304, the diffusion region 302 comprising a first diffusion region portion 316(1) and a second diffusion region portion 316(2), each disposed along a first axis X1 in a first direction (block 402). Forming the diffusion region 302 further includes forming the first diffusion region portion 316(1) and the second diffusion region portion 316(2) to intersect along a second axis Y2 in a second direction orthogonal to the first direction, the first diffusion region portion 316(1) having a first width W1 in the second direction and the second diffusion region portion 316(2) having a second width W2 greater than the first width W1 in the second direction (block 404). The method further includes forming a first gate 306(2) along the second axis Y2 on the diffusion region 302, wherein the first gate 306(2) comprises a first gate first side G1S1 on the first diffusion region portion 316(1) and a first gate second side G1S2 on the second diffusion region portion 316(2) (block 406).

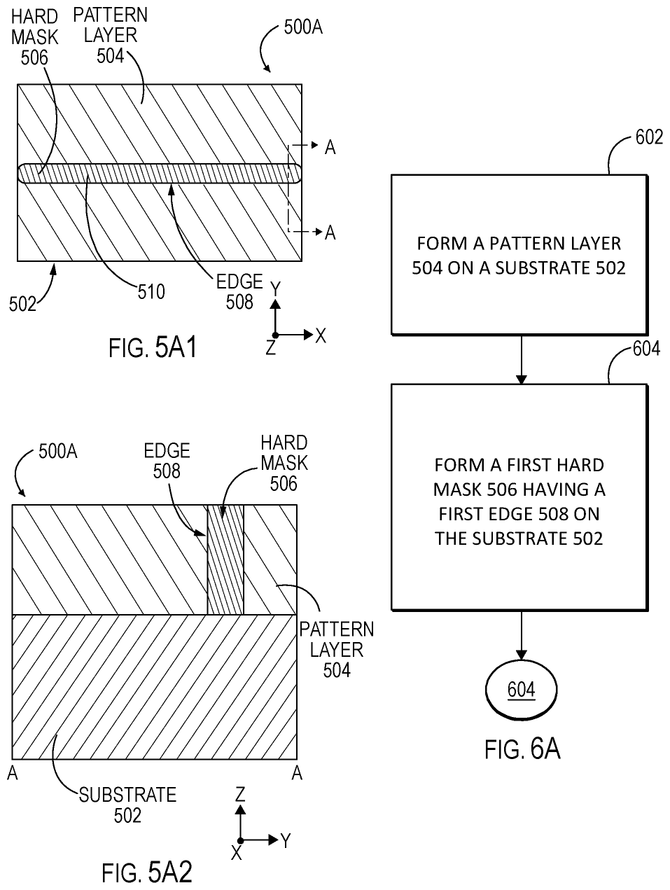

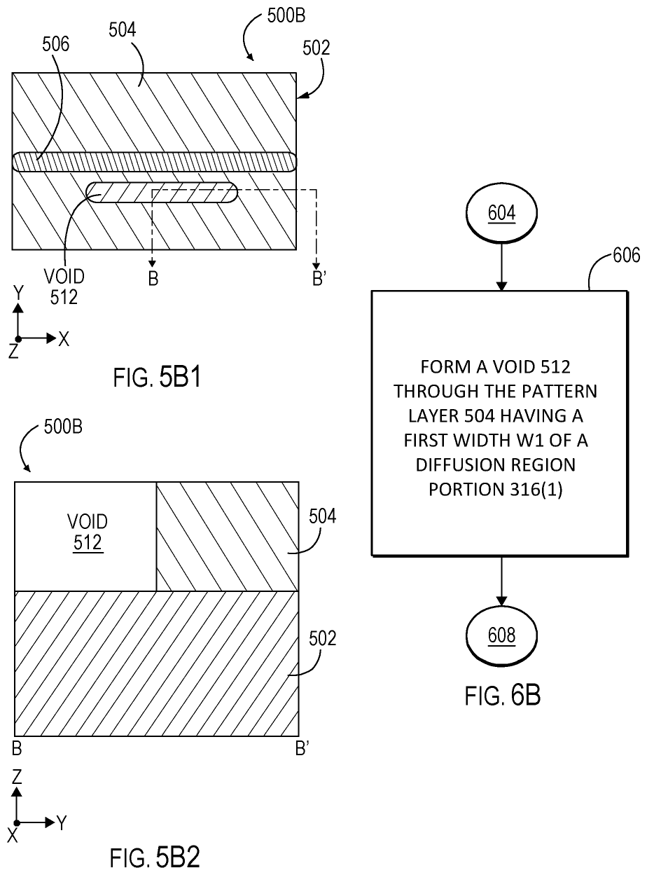

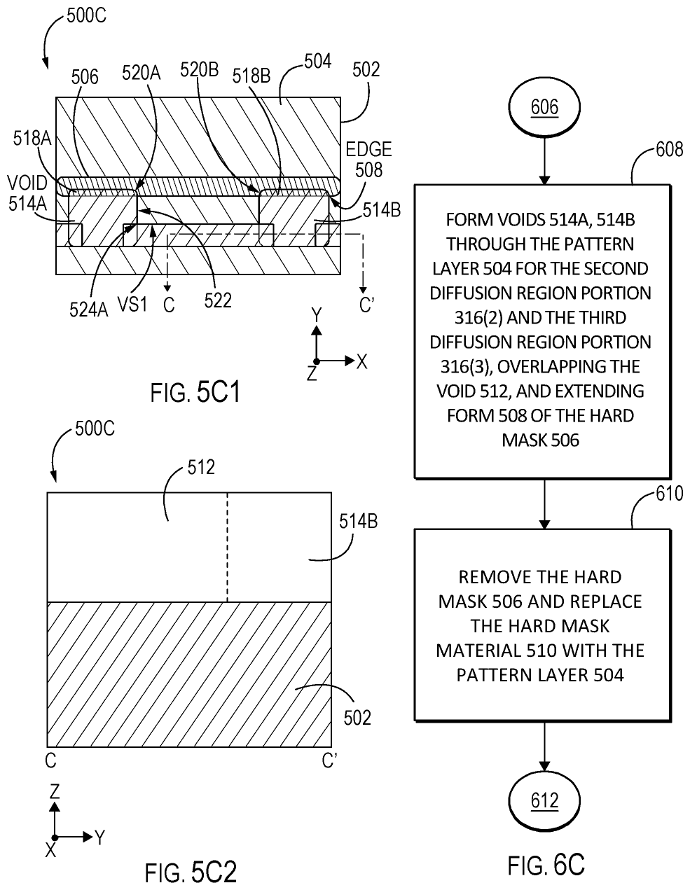

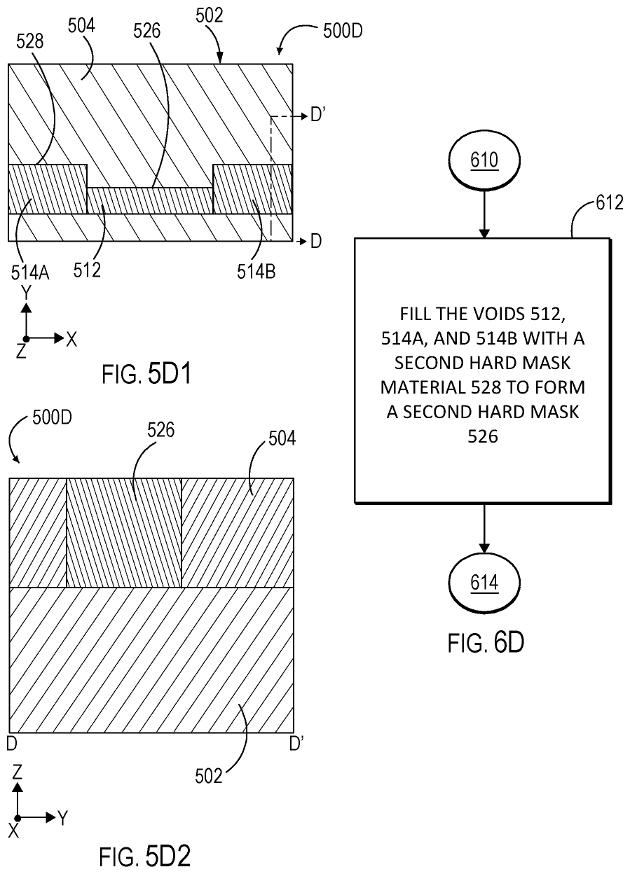

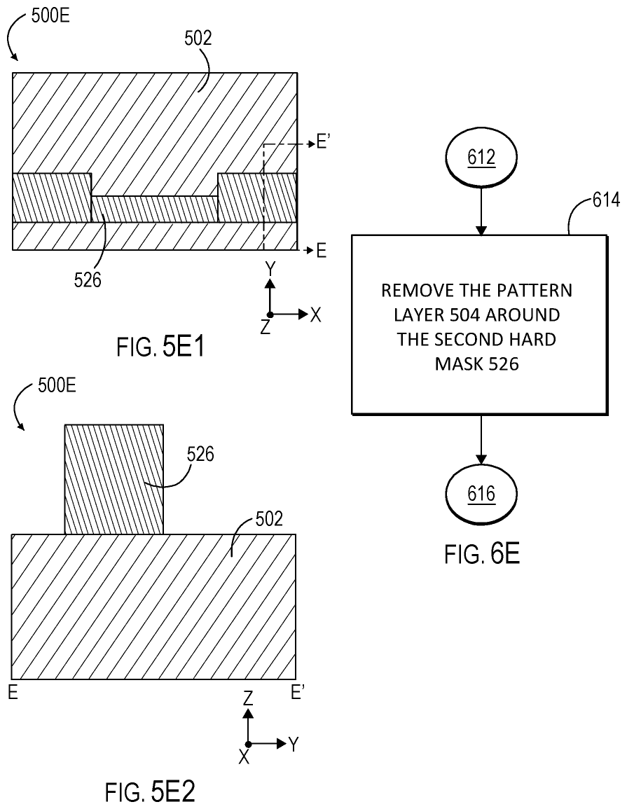

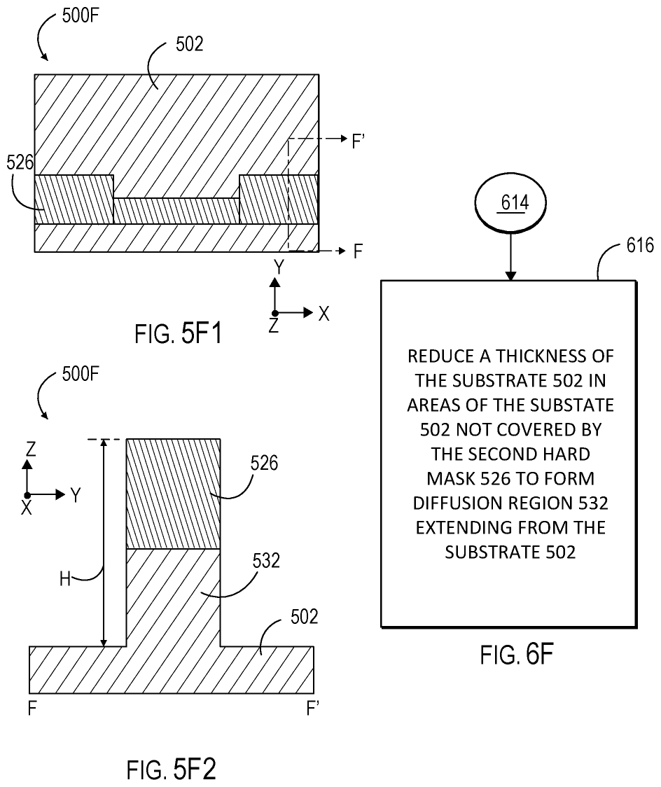

FIGS. 5A1-5F2 illustrate stages of fabrication of the row cell circuit 300 as described in a flow chart 600 in FIGS. 6A-6F.

FIG. 5A1 is a top view of a substrate 502 on which the row cell circuit 300 is formed at a first fabrication stage 500A. The substrate 502 corresponds to the substrate 304 in FIG. 3. FIG. 5A2 is a cross-sectional side view at cross-section A-A′ indicated in FIG. 5A1. The fabrication stage 500A includes forming a pattern layer 504 on the substrate 502 (block 602). The pattern layer 504 may be tetraethyl orthosilicate (TEOS) or silicon dioxide (SiO₂), for example, but is not limited in this regard. Fabrication stage 500A also includes forming a first hard mask 506 having a first edge 508 on the substrate 502 (block 604). Forming the first hard mask 506 in the pattern layer 504 includes creating a void (not shown) extending through the pattern layer 504 to the substrate 502 in the desired shape of the hard mask 506 and filling the void with a hard mask material 510, which may be aluminum oxide (Al₂O₃), for example. The hard mask 506 includes the first edge 508 extending in a straight line along an axis A1. Top surfaces of the pattern layer 504 and the hard mask 506 are planarized. A top view of the hard mask 506 is shown in FIG. 5A1, and an end view of the hard mask 506 in the X-axis direction is shown in FIG. 5A2.

FIG. 5B1 is a top view of the substrate 502 in a next fabrication stage 500B. in which the first diffusion region portion 316(1) of FIG. 3 of the row cell circuit 300 in FIG. 3 is formed. FIG. 5B2 is a cross-sectional view of the substrate 502 at cross-section B-B′ at the fabrication stage 500B. Fabrication stage 500B includes forming a void 512 through the pattern layer 504 having the first width W1 of the first diffusion region portion 316(1) (block 606). The void 512 extends through the pattern layer 504 to the substrate 502.

It is noted that the void 512 may inadvertently have rounded corners, illustrating an example of a reduction in granularity/specificity of process limitations at smaller technology nodes. FIG. 5B2 shows a cross-sectional side view of the cross-section B-B′ through the pattern layer 504 (right) and the void 512 (left).

FIG. 5C1 is a top view of the substrate 502 in a next fabrication stage 500C of the row cell circuit 300, at which the second diffusion region portion 316(2) and the third diffusion region portion 316(3) are formed. FIG. 5C2 is a cross-sectional view at the cross-section C-C′ of the substrate 502 at the fabrication stage 500C. Fabrication stage 500C includes forming voids 514A and 514B through the pattern layer 504 for the second diffusion region portion 316(2) and the third diffusion region portion 316(3), overlapping the void 512, and having the width W2 extending from the edge 508 of the hard mask 506 (block 608). It is noted that areas 518A and 518B illustrate the shapes of portions of the voids 514A and 514B that would have been formed in the pattern layer 504 in the absence of the hard mask 506. However, due to the presence of the hard mask 506 and the resistance of the hard mask 506 to processes used for etching the pattern layer 504, the areas 518A and 518B are not formed. Instead, the voids 514A and 514B stop at the edge 508 of the hard mask 506, forming sharp, square corners 520A and 520B.

For example, where a first end 522 (e.g., a straight line) of the first void intersects with the edge 508 of the hard mask 506, a sharp, square corner 520A (e.g., an inside corner) is formed in the pattern layer 504. In addition, where the first end 522 overlaps (at a square corner) a first side VS1 of the void 512, another sharp, square corner 524A (e.g., an outside corner) of the pattern layer 504 is formed. Despite the pattern limitations that cause rounded corners by a single mask pattern, the exemplary process of employing a two-mask/etch process makes it possible to create sharper corners. These square corners 520A and 524A make it possible for the diffusion region 302, which will be formed from the voids 512 and 514A, 514B, to abruptly transition from the first width W1 to the second width W2, avoiding the gradual angles that cause fabrication defects, as discussed above.

Fabrication stage 500C also includes removing the hard mask 506 and replacing the hard mask material 510 with the pattern layer 504 (block 610).

FIG. 5C2 shows that the pattern layer 504 has been removed from the voids 512 and 514B down to the substrate 502. The shapes of the voids 512, 514A, and 514B, as seen from the top view in FIG. 5C1, correspond to the shape of the diffusion region 302 in FIG. 3.

FIG. 5D1 is a top view of the substrate 502 in a next fabrication stage 500D of the row cell circuit 300, at which a second hard mask 526 in the shape of the diffusion region 302 is formed. FIG. 5D2 is a cross-sectional side view at the cross-section D-D′ in FIG. 5D1. Fabrication stage 500D includes filling the voids 512, 514A, and 514B with a second hard mask material 528 to form the second hard mask 526 (block 612). For example, the second hard mask material 528 may be silicon nitride (Si3N4). The second hard mask material 528 is selected to be resistant to a process for removing the pattern layer 504 and for subsequent processing of the substrate 502.

FIG. 5E1 is a top view of the substrate 502 in a next fabrication stage 500E of the row cell circuit 300. Fabrication stage 500E includes removing the pattern layer 504 around the second hard mask 526 (block 614), which leaves the second hard mask 526 on a top surface of the substrate 502. FIG. 5D2 is a cross-sectional side view at the cross-section E-E′ in FIG. 5D1, through the second hard mask 526 formed in fabrication stage 500D on top of the substrate 502. In the top view shown in FIG. 5E1, the second hard mask 526 has the shape of the diffusion region 302.

FIG. 5F1 is a top view of the substrate 502 in a fabrication stage 500F of the row cell circuit 300 at which a diffusion region 532 is formed from the second hard mask 526. In the top view shown in FIG. 5F1, no change is apparent from FIG. 5E1. However, as shown in FIG. 5F2 at cross-section F-F′, fabrication stage 500F includes reducing a thickness of the substrate 502 in areas of the substrate 502 that are not covered by the second hard mask 526 to form the diffusion region 532 extending from the substrate 502 (block 616). Because the diffusion region 532 has not been reduced in thickness, like the surrounding areas of the substrate 502, the diffusion region 532 extends vertically from those areas. In this regard, the sides of the diffusion region 532 extend vertically (in the Z-axis direction). The sides of the first, second, and third diffusion region portions 316(1)-316(3) may be portions of the sides of the diffusion region 532. For example, the first portion first side D1S1, the first portion second side D1S2, the second portion first side D2S1, the second portion second side D2S2, and the second portion end D2E may be portions of the vertical surfaces of the diffusion region 532.

Reducing the thickness of the substrate 502 may be achieved in an etching process that effectively removes the material 530 (e.g., silicon) of the substrate 502 but does not remove the second hard mask 526. This is shown more clearly in the cross-sectional side view in FIG. 5F2, where the substrate 502 has been reduced by a height H. In processes known in the art, the nanosheets 312 and the nanosheet diffusion region 314 are formed in subsequent subtractive processes from the diffusion region 532.

The logic circuits, including row cell circuits having different heights according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

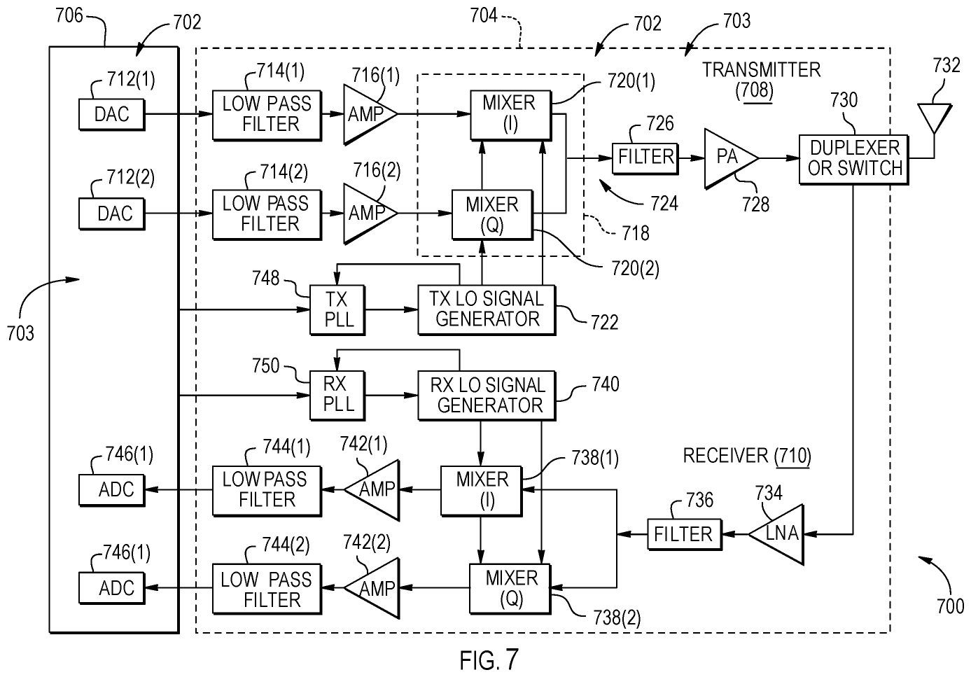

In this regard, FIG. 7 illustrates an exemplary wireless communications device 700 that includes radio frequency (RF) components formed from one or more ICs 702, wherein any of the ICs 702 can include logic circuits implemented in row cell circuits with abrupt transitions in the width of the diffusion regions to avoid electrical shorts and leakage current and also to improve area efficiency, as illustrated in FIG. 3, and according to any aspects disclosed herein. The wireless communications device 700 may include or be provided in any of the above-referenced devices as examples. As shown in FIG. 7, the wireless communications device 700 includes a transceiver 704 and a data processor 706. The data processor 706 may include a memory to store data and program codes. The transceiver 704 includes a transmitter 708 and a receiver 710, which support bi-directional communications. In general, the wireless communications device 700 may include any number of transmitters 708 and/or receivers 710 for any number of communication systems and frequency bands. All or a portion of the transceiver 704 may be implemented on one or more analog ICs, RF ICs (RFICs), mixed-signal ICs, etc.

The transmitter 708 or the receiver 710 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into I and Q analog output signals, e.g., I and Q output currents, for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals from a TX LO signal generator 722 through mixers 720(1), 720(2) to provide an upconverted signal 724. A filter 726 filters the upconverted signal 724 to remove undesired signals caused by the frequency upconversion as well as noise in a receive frequency band. A power amplifier (PA) 728 amplifies the upconverted signal 724 from the filter 726 to obtain the desired output power level and provides a transmit RF signal. The transmit RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Downconversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by AMPs 742(1), 742(2) and further filtered by lowpass filters 744(1), 744(2) to obtain I and Q analog input signals, which are provided to the data processor 706. In this example, the data processor 706 includes analog-to-digital converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency upconversion, while the RX LO signal generator 740 generates the I and Q RX LO signals used for frequency downconversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

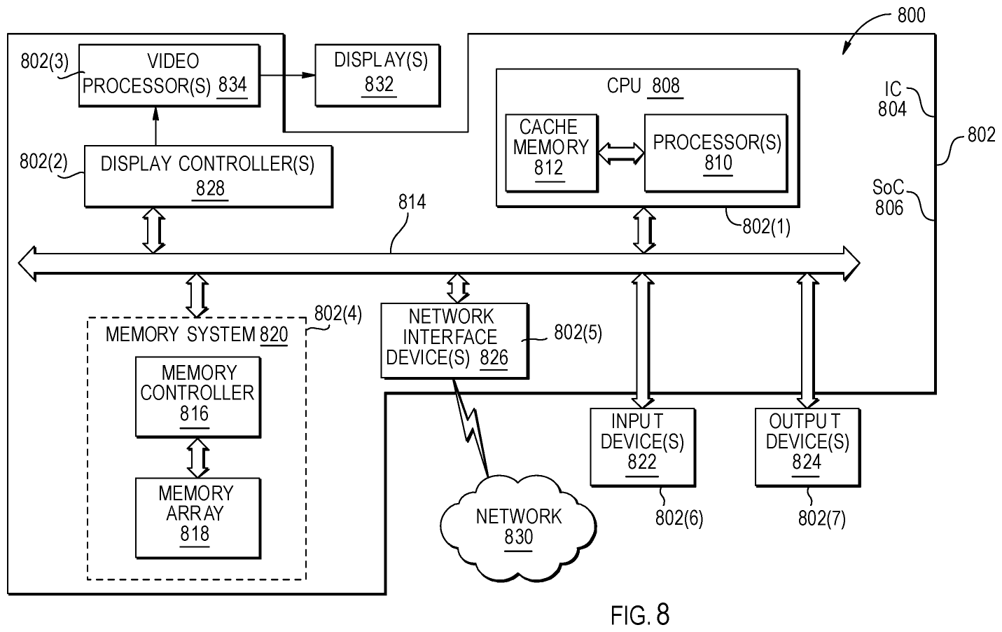

FIG. 8 illustrates an example of a processor-based system 800 that can include logic circuits implemented in row cell circuits with abrupt transitions in the width of the diffusion regions to avoid electrical shorts and leakage current and also to improve area efficiency, as illustrated in FIG. 3. In this example, the processor-based system 800 includes one or more central processor units (CPUs) 808, which may also be referred to as CPU or processor cores, each including one or more processors 810. The CPU(s) 808 may have cache memory 812 coupled to the processor(s) 810 for rapid access to temporarily stored data. The CPU(s) 808 is coupled to a system bus 814 and can intercouple master and slave devices included in the processor-based system 800. As is well known, the CPU(s) 808 communicates with these other devices by exchanging address, control, and data information over the system bus 814. For example, the CPU(s) 808 can communicate bus transaction requests to a memory controller 816 as an example of a slave device. Although not illustrated in FIG. 8, multiple system buses 814 could be provided; wherein each system bus 814 constitutes a different fabric.

Other master and slave devices can be connected to the system bus 814. As illustrated in FIG. 8, these devices can include a memory system 820 that includes the memory controller 816 and one or more memory arrays 818, one or more input devices 822, one or more output devices 824, one or more network interface devices 826, and one or more display controllers 828, as examples. The input device(s) 822 can include any type of input device, including, but not limited to, input keys, switches, voice processors, etc. The output device(s) 824 can include any type of output device, including, but not limited to, audio, video, other visual indicators, etc. The network interface device(s) 826 can be any device configured to allow an exchange of data to and from a network 830. The network 830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 826 can be configured to support any type of communications protocol desired.

The CPU(s) 808 may also be configured to access the display controller(s) 828 over the system bus 814 to control information sent to one or more displays 832. The display controller(s) 828 sends information to the display(s) 832 to be displayed via one or more video processors 834, which process the information to be displayed into a format suitable for the display(s) 832. The display(s) 832 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Implementation examples are described in the following numbered clauses:

1. A row cell circuit, comprising:
a diffusion region on a substrate, the diffusion region comprising a first diffusion region portion and a second diffusion region portion, each disposed along a first axis in a first direction, wherein:
   the first diffusion region portion and the second diffusion region portion intersect along a second axis in a second direction orthogonal to the first direction;
   the first diffusion region portion has a first width in the second direction; and
   the second diffusion region portion has a second width greater than the first width in the second direction; and
a first gate disposed along the second axis on the diffusion region, wherein the first gate comprises a first gate first side on the first diffusion region portion and a first gate second side on the second diffusion region portion.
   2. The row cell circuit of clause 1, wherein:
the first diffusion region portion comprises a first portion first side and a first portion second side, each orthogonal to the first gate first side; and
the second diffusion region portion comprises a second portion first side and a second portion second side, each orthogonal to the first gate second side.
   3. The row cell circuit of clause 2, wherein the first portion second side and the second portion second side extend along a third axis in the first direction.
   4. The row cell circuit of clause 2 or clause 3, wherein the second diffusion region portion further comprises a second portion end disposed along the second axis,
wherein the second portion end of the second diffusion region portion is orthogonal to the first portion first side of the first diffusion region portion.
   5. The row cell circuit of clause 4, wherein the second portion first side is orthogonal to the second portion end.
   6. The row cell circuit of clause 1, wherein the first gate comprises a dummy gate.
   7. The row cell circuit of any of clause 1 to clause 6, further comprising a nanosheet disposed within the first gate and above the diffusion region in a vertical direction orthogonal to the first direction and the second direction.
   8. The row cell circuit of clause 7, wherein the nanosheet comprises:
a first nanosheet portion having the first width;
a second nanosheet portion having the second width; and
a right-angle corner between the first nanosheet portion and the second nanosheet portion.
   9. The row cell circuit of clause 6 or clause 7, wherein the nanosheet comprises a same material as the diffusion region.
   10. The row cell circuit of any of clause 2 to clause 9, further comprising:
a second gate disposed along a fourth axis in the second direction on the diffusion region adjacent to the first gate first side, wherein the second gate comprises a second gate first side and a second gate second side; and
a first nanosheet disposed between the second gate first side and the second gate second side.
   11. The row cell circuit of any of clause 7 to clause 10, wherein the nanosheet has the first width in the second direction.
   12. The row cell circuit of any of clause 7 to clause 10, further comprising:
a third gate disposed along the fourth axis in the second direction on the diffusion region adjacent to the first gate second side, the third gate comprising:
   a third gate first side;
   a third gate second side; and
   a second nanosheet disposed between the third gate first side and the third gate second side.
      13. The row cell circuit of clause 12, wherein the second nanosheet has the second width in the second direction.
      14. The row cell circuit of any of clause 7 to clause 13, wherein:
the first diffusion region portion extends between the first gate first side and the second gate second side; and
the first portion first side and the first portion second side are each orthogonal to the first gate first side and the second gate second side.
   15. The row cell circuit of any of clause 10 to clause 14, further comprising a first source/drain region disposed between the first gate and the second gate on the first diffusion region portion, the first source/drain region electrically coupled to the first nanosheet.
   16. The row cell circuit of any of clause 12 to clause 15, wherein:
the second diffusion region portion extends between the first gate second side and the third gate first side; and
the second portion first side and the second portion second side are each orthogonal to the first gate second side and the third gate first side.
   17. The row cell circuit of any of clause 12 to clause 16, further comprising a second source/drain region disposed between the first gate second side and the third gate first side on the second diffusion region portion, the second source/drain region electrically coupled to the second nanosheet.
   18. The row cell circuit of any of clause 2 to clause 17, wherein the first portion first side, the first portion second side, the second portion first side, and the second portion second side each comprise surfaces extending in a vertical direction orthogonal to the first direction and the second direction.
   19. The row cell circuit of any of clause 2 to clause 18 integrated into an integrated circuit (IC).
   20. The row cell circuit of any of clause 2 to clause 19, integrated into a device selected from the group consisting of: a set-top box; an entertainment unit; a navigation device; a communications device; a fixed location data unit; a mobile location data unit; a global positioning system (GPS) device; a mobile phone; a cellular phone; smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
   21. A method of fabricating a row cell circuit, comprising:
forming a diffusion region on a substrate, the diffusion region comprising a first diffusion region portion and a second diffusion region portion, each disposed along a first axis in a first direction, wherein forming the diffusion region on the substrate further comprises:
   forming the first diffusion region portion and the second diffusion region portion intersecting along a second axis in a second direction orthogonal to the first direction;
   forming the first diffusion region portion having a first width in the second direction; and
   forming the second diffusion region portion having a second width greater than the first width in the second direction; and
forming a first gate along the second axis on the diffusion region, wherein the first gate comprises a first gate first side on the first diffusion region portion and a first gate second side on the second diffusion region portion.
   22. The method of clause 21, wherein:
forming the first diffusion region portion comprises:
   forming the first diffusion region portion in a first process, the first diffusion region portion comprising:
      a first portion first side extending along a third axis in the first direction; and
      a first portion second side parallel to the first portion first side; and
   forming the second diffusion region portion in a second process, the second diffusion region portion comprising:
      a second portion first side extending along the third axis in the first direction;
      a second portion second side parallel to the second portion first side; and
      a second portion end disposed along the second axis and at a right angle to the first portion first side.
         23. The method of clause 22, further comprising:
forming a hard mask comprising a first edge disposed along a fourth axis extending in the first direction; and
forming a pattern for the second diffusion region portion overlapping the first edge of the hard mask.
   24. An integrated circuit (IC) comprising:
a logic circuit disposed on a substrate, the logic circuit comprising a plurality of row cell circuits, each row cell circuit comprising:
   a diffusion region on a substrate, the diffusion region comprising a first diffusion region portion and a second diffusion region portion, each disposed along a first axis in a first direction, wherein:
      the first diffusion region portion and the second diffusion region portion intersect along a second axis in a second direction orthogonal to the first direction;
      the first diffusion region portion has a first width in the second direction; and
      the second diffusion region portion has a second width greater than the first width in the second direction; and
   a first gate disposed along the second axis on the diffusion region, wherein the first gate comprises a first gate first side on the first diffusion region portion and a first gate second side on the second diffusion region portion.

What is claimed is:

1. A row cell circuit, comprising:
a diffusion region on a substrate, the diffusion region comprising a first diffusion region portion and a second diffusion region portion, each disposed along a first axis in a first direction, wherein:
the first diffusion region portion and the second diffusion region portion intersect along a second axis in a second direction orthogonal to the first direction;
the first diffusion region portion has a first width in the second direction; and
the second diffusion region portion has a second width greater than the first width in the second direction; and
a first gate disposed along the second axis on the diffusion region, wherein the first gate comprises a first gate first side on the first diffusion region portion and a first gate second side on the second diffusion region portion.

2. The row cell circuit of claim 1, wherein:
the first diffusion region portion comprises a first portion first side and a first portion second side, each orthogonal to the first gate first side; and
the second diffusion region portion comprises a second portion first side and a second portion second side, each orthogonal to the first gate second side.

3. The row cell circuit of claim 1, wherein the first portion second side and the second portion second side extend along a third axis in the first direction.

4. The row cell circuit of claim 2, wherein the second diffusion region portion further comprises a second portion end disposed along the second axis,
wherein the second portion end of the second diffusion region portion is orthogonal to the first portion first side of the first diffusion region portion.

5. The row cell circuit of claim 4, wherein the second portion first side is orthogonal to the second portion end.

6. The row cell circuit of claim 1, wherein the first gate comprises a dummy gate.

7. The row cell circuit of claim 6, further comprising a nanosheet disposed within the first gate and above the diffusion region in a vertical direction orthogonal to the first direction and the second direction.

8. The row cell circuit of claim 7, wherein the nanosheet comprises:
a first nanosheet portion having the first width;
a second nanosheet portion having the second width; and
a right-angle corner between the first nanosheet portion and the second nanosheet portion.

9. The row cell circuit of claim 7, wherein the nanosheet comprises a same material as the diffusion region.

10. The row cell circuit of claim 2, further comprising:
a second gate disposed along a fourth axis in the second direction on the diffusion region adjacent to the first gate first side, wherein the second gate

[symbol]

13. The row cell circuit of claim 12, wherein the second nanosheet has the second width in the second direction.

14. The row cell circuit of claim 10, wherein:
the first diffusion region portion extends between the first gate first side and the second gate second side; and
the first portion first side and the first portion second side are each orthogonal to the first gate first side and the second gate second side.

15. The row cell circuit of claim 10, further comprising a first source/drain region disposed between the first gate and the second gate on the first diffusion region portion, the first source/drain region electrically coupled to the first nanosheet.

16. The row cell circuit of claim 12, wherein:
the second diffusion region portion extends between the first gate second side and the third gate first side; and
the second portion first side and the second portion second side are each orthogonal to the first gate second side and the third gate first side.

17. The row cell circuit of claim 12, further comprising a second source/drain region disposed between the first gate second side and the third gate first side on the second diffusion region portion, the second source/drain region electrically coupled to the second nanosheet.

18. The row cell circuit of claim 2, wherein the first portion first side, the first portion second side, the second portion first side, and the second portion second side comprise surfaces extending in a vertical direction orthogonal to the first direction and the second direction.

19. The row cell circuit of claim 1 integrated into an integrated circuit (IC).

20. The row cell circuit of claim 1, integrated into a device selected from the group consisting of: a set-top box; an entertainment unit; a navigation device; a communications device; a fixed location data unit; a mobile location data unit; a global positioning system (GPS) device; a mobile phone; a cellular phone; smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

21. A method of fabricating a row cell circuit, comprising:
forming a diffusion region on a substrate, the diffusion region comprising a first diffusion region portion and a second diffusion region portion, each disposed along a first axis in a first direction, wherein forming the diffusion region on the substrate further comprises:
forming the first diffusion region portion and the second diffusion region portion intersecting along a second axis in a second direction orthogonal to the first direction;
forming the first diffusion region portion having a first width in the second direction; and
forming the second diffusion region portion having a second width greater than the first width in the second direction; and
forming a first gate along the second axis on the diffusion region, wherein the first gate comprises a first gate first side on the first diffusion region portion and a first gate second side on the second diffusion region portion.

22. The method of claim 21, wherein:
forming the first diffusion region portion comprises:
forming the first diffusion region portion in a first process, the first diffusion region portion comprising:
a first portion first side extending along a third axis in the first direction; and
a first portion second side parallel to the first portion first side; and
forming the second diffusion region portion in a second process, the second diffusion region portion comprising:
a second portion first side extending along the third axis in the first direction;
a second portion second side parallel to the second portion first side; and
a second portion end disposed along the second axis and at a right angle to the first portion first side.

23. The method of claim 22, further comprising:
forming a hard mask comprising a first edge disposed along a fourth axis extending in the first direction; and
forming a pattern for the second diffusion region portion overlapping the first edge of the hard mask.

24. An integrated circuit (IC) comprising:
a logic circuit disposed on a substrate, the logic circuit comprising a plurality of row cell circuits, each row cell circuit comprising:
a diffusion region on a substrate, the diffusion region comprising a first diffusion region portion and a second diffusion region portion,
each disposed along a first axis in a first direction, wherein:
the first diffusion region portion and the second diffusion region portion intersect along a second axis in a second direction orthogonal to the first direction;
the first diffusion region portion has a first width in the second direction; and
the second diffusion region portion has a second width greater than the first width in the second direction; and
a first gate disposed along the second axis on the diffusion region, wherein the first gate comprises a first gate first side on the first diffusion region portion and a first gate second side on the second diffusion region portion.
